(19) United States
(12) Patent Application Publication
(10) Pub. No.: US 2021/0262077 A1
(43) Pub. Date: Aug. 26, 2021

(54) TANTALUM PENTOXIDE BASED LOW-LOSS METASURFACE OPTICS FOR UV APPLICATIONS

(71) Applicants: University of Maryland, College Park, College Park, MD (US); Government of the United States of America as represented by the Secretary of Commerce, Gaithersburg, MD (US)

(72) Inventors: Cheng ZHANG, Gaithersburg, MD (US); Wenqi ZHU, Vienna, VA (US); Amit Kumar AGRAWAL, Rockville, MD (US); David R. CARLSON, Boulder, CO (US); Henri LEZEC, Silver Spring, MD (US)

(21) Appl. No.: 17/315,108

(22) Filed: May 7, 2021

Related U.S. Application Data
(63) Continuation-in-part of application No. 17/136,277, filed on Dec. 29, 2020.
(60) Provisional application No. 63/022,118, filed on May 8, 2020.
(60) Provisional application No. 62/956,875, filed on Jan. 3, 2020.

(51) Int. Cl. C23C 14/00; C23C 14/08; C23C 14/58; G02F 1/00; C23C 14/34; G02B 5/30; G02B 5/18

(52) U.S. Cl. CPC C23C 14/0036; C23C 14/083; C23C 14/5873; G02B 5/1866; C23C 14/3471; G02B 5/3091; G02B 5/3075; G02F 1/0054

(57) ABSTRACT

High-performance optical-metasurface-based platform configured with the use of Tantalum Pentoxide to operate with extremely low levels of loss at frequencies of UV light and, in particular, in mid- and near-UV ranges and performing multiple optical-wavefront-shaping functions (among which there are high-numerical-aperture lensing, accelerating beam generation, and hologram projection). Process of fabrication of such metasurface producing near-zero levels of optical loss and employing the otherwise standard etching methodologies. Embodiments facilitate the development of low-form-factor, multifunctional ultraviolet nanophotonic platforms based on flat optical components and enabling diverse applications including lithography, imaging, spectroscopy, and quantum information processing.

### CROSS REFERENCE TO RELATED APPLICATIONS

This US Patent Application claims the benefit of and priority from the U.S. Provisional Patent Application No. 63/022,118 filed on May 8, 2020. This patent application is also a continuation-in-part for the U.S. patent application Ser. No. 17/136,277 filed on Dec. 29, 2020, which in turn claims priority from the U.S. Provisional patent Application No. 62/956,875 filed on Jan. 3, 2020. The disclosure of each of the above-identified applications is incorporated herein by reference.

### STATEMENT REGARDING FEDERALLY-SPONSORED RESEARCH OR DEVELOPMENT

This invention was made with government support under contract 70NANB14H209 awarded by the National Institute of Standards and Technology. The government has certain rights in the invention.

### TECHNICAL FIELD

The invention relates generally to a system, device, materials, and methods for metasurface-based optics and, in particular, to metasurface-based optical devices and systems configured to be fabricated with absence of the Damascene-type of processing but, instead, relying on conventional lithography/etching processes, and to operate with extremely low levels of optical loss the mid- and near-ultraviolet (UV) portion of the electromagnetic spectrum.

### RELATED ART

Recent years have witnessed rapid development of all-dielectric metasurfaces, characterized by low optical loss and ease of transmission-mode operation, for spatial shaping of optical wavefronts in a compact and integration-friendly manner. Researchers have demonstrated an array of high-performance, all-dielectric metasurfaces operating in the infrared and visible regimes, using materials such as Silicon (Si), Titanium Oxide (TiO₂), and Gallium Nitride (GaN).

One natural trend for the future development of all-dielectric metasurfaces is to attempt extend the operation frequencies at which such metasurfaces can successfully operate into the ultraviolet (UV) regime (which is a technologically important spectral regime, employed by diverse applications including photolithography, spectroscopy, high-resolution imaging, atomic trapping and quantum optics).

Towards this goal, for example, metasurfaces employing crystalline-Si have been attempted, which operate down to the mid-UV (free-space wavelength range of approximately 280 nm≤λ₀≤315 nm). But these devices are fabricated through a dedicated crystalline-Si membrane transfer process, and at the same time, their operational efficiencies remain limited by the severe absorption loss at frequencies corresponding to energies above the bandgap of Si.

In contrast, higher device efficiencies could be achieved by employing UV-transparent dielectric materials. Examples of such materials include Niobium Pentoxide (Nb₂O₅) (at wavelengths of approximately 315 nm≤λ₀≤380 nm). Additional examples include Hafnium Oxide (HfO₂), already shown to be used for formation of metasurfaces operating successfully at the record-short, deep-UV wavelengths. In a latter demonstration, however, the fabrication of the metasurfaces required the development of a judicious resist-based Damascene process incorporating low-temperature atomic layer deposition (ALD) of the target dielectric material (which is, as would be appreciated by a skilled artisan, substantially more complex than a conventional CMOS-like process).

### SUMMARY OF THE INVENTION

Embodiments of the invention provide a method for fabricating an all-dielectric metasurface-based optical device including at least one of a metalens, a metahologram, and an Airy beam generator. The method includes a step of utilizing tantalum pentoxide material target to deposit and etch, on a chosen substrate, a tantalum pentoxide layer under such conditions that the tantalum pentoxide layer has a submicron thickness and an extinction coefficient smaller than 0.1 at each target wavelength within a range from at least 277 nm to about 1700 nm and that the device has optical transmittance of at least 40% at every operational wavelength within a range from about 280 nm to about 380 nm.

Embodiments additionally provide a method that includes a step of forming a preform layer by reactive sputtering, in a sputtering chamber, of tantalum pentoxide on a chosen substrate while simultaneously reducing an extinction coefficient of such preform layer below 0.1 at each target wavelength within a range from at least 277 nm to about 800 nm; and a step of etching such preform layer to create the sub-wavelength-scaled pattern structure that is dimensioned to operate as at least one of a refractive optical element, a diffractive optical element, a birefringent optical element, and a resonant optical element at an operational wavelength in a mid-UV range and/or a near-UV range of an electromagnetic spectrum. In at least one case, the step of forming may involve simultaneously reducing the extinction coefficient to a value below 0.01 at each wavelength within a range from at least 292 nm to about 800 nm, while the operational wavelength is defined within a spectral range from about 280 nm to about 380 nm; and/or the step of forming may involve simultaneously reducing the extinction coefficient to a value below 0.001 at each wavelength within a range from at least 297 nm to about 800 nm, while the operational wavelength is within a spectral range from about 280 nm to about 380 nm. In the latter case, the step of forming may additionally include the process of simultaneously reducing the extinction coefficient to a value below 0.001 at each wavelength within a range from about 800 nm to about 1700 nm. Additionally or in the alternative, and in at least one implementation, the step of forming may include simultaneously reducing the extinction coefficient to a value below 0.00001 at each wavelength within a range from at least 299 nm to about 800 nm (while the operational wavelength is within a spectral range from about 280 nm to about 380 nm) and/or simultaneously reducing the extinction coefficient to a value below 0.00001 at each wavelength within a range from about 800 nm to about 1700 nm. In practically every embodiment, the step of forming includes varying a flow of oxygen into the sputtering chamber and/or the step of forming is performed by sputtering tantalum pentoxide while simultaneously maintaining a refractive index of the preform layer above 2.21 at each first wavelength within a range from at least 277 nm to about 800 nm. (At least in the latter case, the step of forming may additionally or in the alternative include sputtering of tantalum pentoxide while simultaneously maintaining the refractive index of said preform layer above 2.0 at each second wavelength within a range from about 800 nm to about 1700 nm; and/or delivering a flow of oxygen into said sputtering chamber at a rate of at least 2 standard cubic centimeters per minute). In substantially every embodiment, the process of etching may be configured to form the target pattern structure that includes only tantalum pentoxide and/or include a process of generating an array of cylindrical columns of tantalum pentoxide of sub-micron height and aspect ratios of at least 5 (here, an aspect ratio of a respective columns defined as a ratio of a height to a transverse dimension of such column). Alternatively or in addition, and in substantially every embodiment, the process of etching may include generating an array of cylindrical columns of tantalum pentoxide of sub-micron height while the array has a spatial period not exceeding the operational wavelength; and/or while such array is a spatially-periodic array with a spatial period having a value within a range from about 50 nm to about 600 nm; and/or such array includes cylindrical pillars having different diameters to form areas of the array characterized by different filling factors. IN at least one implementation. The etching of the preform layer is carried out under conditions described as Ta₂O₅+C₄F₈+O₂→TaFx+COFx+COx.

Embodiments additionally provide a method for operating an optical component that contains the pattern structure fabricated as defined above. Such method for operating includes at least one of the following steps:—changing at least one of a direction of propagation and a degree of divergence of light at the operational wavelength by transmitting said light through the pattern structure with efficiency of at least 40%; —forming an image of an object in said light at the operational wavelength emanating from the object with the use of said pattern structure; and—transmitting said light at the operational wavelength through said pattern structure without forming non-zero diffractive orders of said light.

Embodiments additionally provide a metasurface that includes an optical substrate, and a spatially-periodic two-dimensional array of cylindrical pillars oriented on the optical substrate substantially normally to the optical substrate (such cylindrical pillars include tantalum pentoxide that has extinction coefficient of less than 0.1 at each target wavelength within a range from at least 277 nm to about 1700 nm). Here, a spatial period of the array is substantially constant across an area of the optical substrate occupied by the array while different cylindrical pillars have different diameters to form areas of the array having different filling factors and heights of the cylindrical pillars in the array approximately equal or exceed a free-space operational wavelength chosen within a mid-UV region and a near-UV region of the electromagnetic spectrum such that the metasurface is configured to operate, in transmission of light at said operational wavelength, as at least one of a refractive optical element, a diffractive optical element, a birefringent optical element, and a resonant optical element. In at least one specific case, a cylindrical pillar in the array is dimensioned as an elliptic cylinder and the spatial period does not exceed the operational wavelength such that light, incident onto the metasurface, does not diffract upon transmission through the metasurface. Alternatively or in addition, the operational wavelength may be within a range from about 280 nm to about 380 nm, and a refractive index value of the tantalum pentoxide is greater than 2.0 at each target wavelength. Alternatively or in addition, the tantalum pentoxide material is configured to have a refractive index that is higher than 2.2 at each wavelength between 280 nm and 380 nm and/or an extinction coefficient that is below 0.001 at each wavelength from at least 297 nm to about 1700 nm or even below 0.00001 at each wavelength from at least 299 nm to about 1700 nm.

### BRIEF DESCRIPTION OF THE DRAWINGS

The invention will be more fully understood by referring to the following Detailed Description of Specific Embodiments in conjunction with the Drawings, of which:

FIG. 1A presents plots depicting dependency of measured real and imaginary part of the complex refractive index of Ta₂O₅ film sputter-deposited with the use of the conventional methodology (a, a1) and according to the idea of the invention (b, b1; c, c1)—with different O₂ gas flow rates.

FIG. 1B provides a plot of dispersion of the measured index of refraction n of Ta₂O₅ (sputtered using O₂ flowing at 2 sccm, corresponding to curve c of FIG. 1A) vs. wavelength, across a full spectral range of collected data (192 nm to 1689 nm).

FIG. 1C provides a plot of dispersion of the measured extinction coefficient k of Ta₂O₅ (sputtered using O₂ flowing at 2 sccm, corresponding to curve c1 of FIG. 1A) across a full spectral range of collected data (192 nm to 1689 nm).

FIG. 1D provides a plot of dispersion of the measured extinction coefficient k of Ta₂O₅ (sputtered using O₂ flowing at 2 sccm, corresponding to curve c1 of FIG. 1A) but presented on a log-linear scale across deep-UV (190 nm-280 nm) and mid-UV (280 nm-315 nm) spectral ranges, within which the value of k varies rapidly.

FIG. 2 presents flow-chart of an embodiment of the fabrication process of a patterned tantalum pentoxide layer on the UV-grade fused silica substrate.

FIG. 3 is a schematic representation of a UV metasurface unit cell showing high-aspect-ratio Ta₂O₅ pillar or column of height H and an elliptical cross-section of such pillar or column (principle axes' lengths D₁ and D₂), and a rotation angle θ. The shown single pillar is formed on a SiO₂ substrate.

FIG. 4 is an SEM-image illustrating a portion of an array of multiple pillars (similar to that of FIG. 3 and fabricated according to the idea of the invention) that are generally arranged on a square lattice or array with a with sub-wavelength lattice spacing P to form a metahologram. (Generally, however, as discussed, specific optical functions are achieved by varying at least D₁, D₂, and θ as a function of these nanopillar position(s) within the lattice/array.) This SEM-image of details of metahologram designed for operation at λ₀=325 nm, showing a lattice of approximately 400 nm tall, elliptically-shaped nanopillars of the target material of varying in-plane cross-sections and rotation angles.

FIG. 5 schematically illustrates an embodiment of a polarization-dependent near- and mid-UV metahologram.

FIG. 6: Targeted and measured holographic images projected by the metasurface of FIG. 4, 5 under normally-incident plane-wave illumination L (LCP, left-circular polarization) at λ₀=325 nm. These images read the molecular formula of the utilized dielectric material-Ta2O5. It can be observed that letters with serif fonts were truthfully reconstructed in the holograms. The efficiency (a ratio of the transmitted optical power to that incident onto the metasurface) was around 40% in this example.

FIG. 7 provides a contour plot of the identified figure-of-merit (FoM) as a function of D₁ and D₂ of FIG. 3. The regime 710 indicates FoMs of low values, which correspond to combinations of D₁ and D₂ that satisfy the targeted half-wave-plate-like operation. The chosen pillar geometry for this study is denoted by a star 712.

FIG. 8 is a table summarizing the complementary nature of metasurface-fabrication methodologies employing HfO₂ and Ta₂O₅ for use across the UV spectral range.

Generally, the sizes and relative scales of elements in Drawings may be set to be different from actual ones to appropriately facilitate simplicity, clarity, and understanding of the Drawings. For the same reason, not all elements present in one Drawing may necessarily be shown in another.

### DETAILED DESCRIPTION

A person of ordinary skill in the art can readily appreciate that the major predicament standing in the way of the successful expansion of metasurface-related technologies into the mid- and near-UV spectral range (to say nothing about the deep-UV spectral range) is two-fold: on the one hand, the conventionally-used dielectric materials do not necessarily (and do not typically) possess the levels of optical transmission in that spectral region that is required for efficient use of the metasurface devices (here, Si is the primary example, demonstrating practically-acceptable levels of transmission only in the spectral region that does not extend below about 500 nm). On the other hand, materials that do potentially possess the required low levels of transmission in the UV-range (be it a near-UV spectral range, or a mid-UV spectral range, or a deep-UV spectral range) do not lend themselves to being processed in a well-defined, well-established, and/or well-controllable manner (for example, such materials are not necessarily CMOS compatible). As discussed in U.S. Ser. No. 17/136,277, hafnium oxide is one of such materials. For the purposes of this disclosure and the appended claims, and unless specifically defined otherwise, the terms “near-UV”, “mid-UV”, and “deep-UV” as applied to portions or ranges of the electromagnetic spectrum are defined as and referred to as follows: near-UV range (free-space wavelength range: 315 nm≤λ0≤380 nm; energy range: 3.26 eV≤E0≤3.94 eV); mid-UV range (free-space wavelength range: 280 nm≤λ0≤315 nm; energy range: 3.94 eV≤E0≤4.43 eV), deep-UV range (190 nm≤λ0≤280 nm; 4.43 eV≤E0≤6.53 eV).

This currently-existing hindrance begs the question of whether it is possible to adopt a dielectric material—the one that is successfully and controllably deposited and patterned with the use of a standard, conventional, CMOS-like approach but that is not necessarily transparent enough in the target UV-spectral region—for creation of the metasurfaces in the UV-range by modifying the properties of such material to reduce the level of optical losses at the UV-wavelengths while, at the same time, preserving the compatibility of this material with the conventional lithography-like processing methodologies.

In particular, it is well recognized in related art that films of Ta₂O₅ (that has an intrinsic wide bandgap) deposited using conventional radiofrequency (RF) sputtering inevitably have defects causing sub-bandgap absorption preventing the use of such films for fabrication of practically-useful metasurface-based devices. This disclosure addresses such a problem and presents a technological modification, as a result of which Tantalum Pentoxide Ta₂O₅ (that has been previously known to possess high level of optical losses in the mid- and near-UV spectral region that prevented this material up to-date from being used for construction of metasurfaces) can now be successfully deposited in a conventional sputtering chamber with reduction of the optical losses to the lowest levels unachievable thus far.

Accordingly, embodiments of the discussed invention demonstrate a new all-dielectric, UV-metasurface optical system platform based on Tantalum Pentoxide and methodology of fabricating such a platform. The choice of this material for the stated goals is justified at least by (i) its wide bandgap value Eₐ˜4.0 eV (corresponding to 309 nm), which at least in theory can enable the low-loss metasurface operation across the whole near-UV and part of the mid-UV ranges (in contrast to the Si- or Nb₂O₅-based devices); (ii) possible use of high-aspect-ratio, reactive ion etching (RIE) chemistries using fluorine-based gases, enabling a straightforward and fast-turnaround fabrication process (in contrast to the Nb₂O₅- or HfO₂-based devices); (iii) large nonlinear coefficients of such material, potentially enabling the implementation of nonlinear metasurfaces for harmonic generation, optical switching and modulation, as well as quantum information processing.

In fact, as the skilled artisan will readily recognize, some of the properties of Ta₂O₅ (especially in the UV portion of the spectrum) are superior to those of Si₃N₄ (used as the state-of-the art material in the field of nanophotonics, for example):

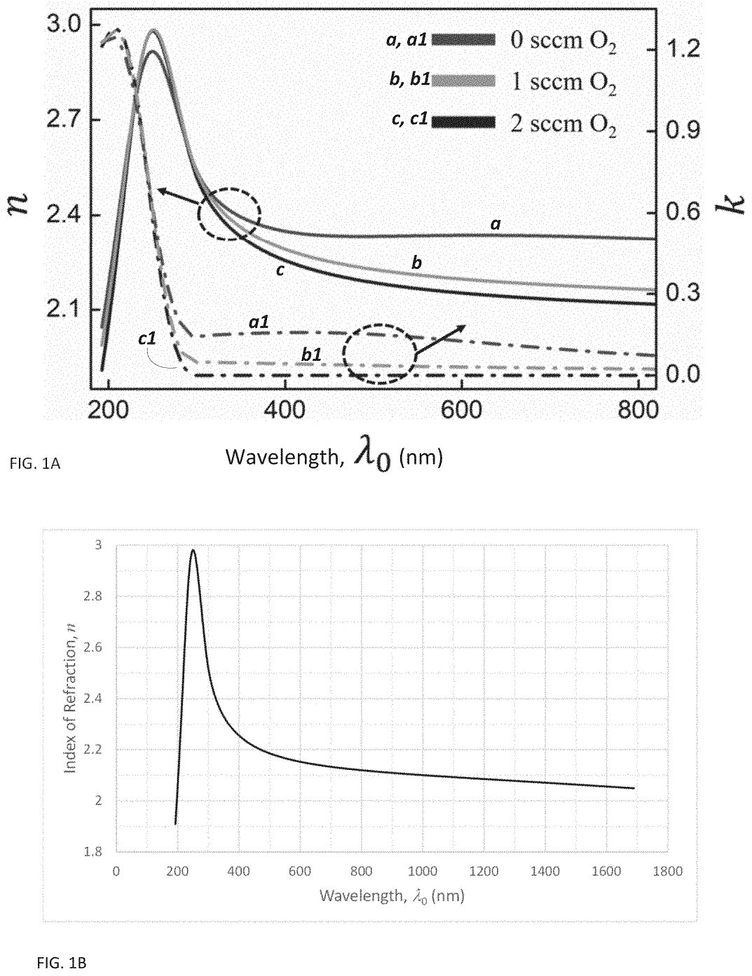

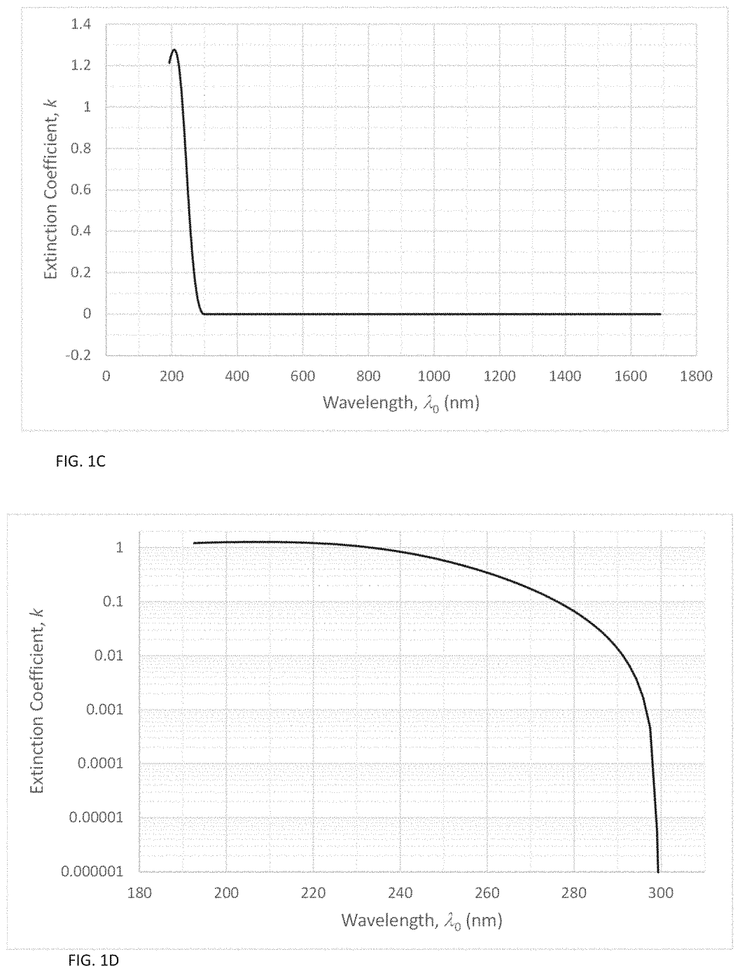

Plots a, a1 of FIG. 1A illustrate the refractive index n and the extinction coefficient k (expressing high values of sub-band absorption that are not practically acceptable for the applications in nanophotonics) of Ta₂O₅ deposited, in the form of films, with the use conventional RF-sputtering. To address this issue, a precisely limited in terms of used chemistry reactive sputtering process was devised, during which the content of oxygen (O₂) gas in the sputtering chamber was judiciously modified. With the increase of O₂ gas flow rate through the chamber during the deposition of the target Ta₂O₅, the sputtered Ta₂O₅ film exhibited a reduced extinction coefficient k (as shown by curves b1, c1) that could be varied as a function of the O₂ flow rate. With an O₂ gas flow rate of about 1 standard cubic centimeters per minute (sccm), the preform layer of Ta₂O₅ film, while being deposited on the UV-grade fused silica substrate, was simultaneously exhibiting the reduction of the extinction coefficient below 0.08 at each target wavelength within a range from at least 310 nm to about 800 nm. At a rate of 2 sccm (curves c, c1), the deposited Ta₂O₅ film demonstrated a refractive index n>2.21 over the whole mid- and near-UV range, as well as negligible absorption coefficient k (with values substantially equal to zero, which is interpreted within an experimental measurement error) at each wavelength within a range from at least 300 nm to about 800 nm). It is understood that in the intermediate regime—that is, during the sputtering enhanced with the flow of oxygen at a two different rates chosen between 1 and 2 sccm—the formation of the tantalum pentoxide preform film on the substrate included simultaneous reduction of the extinction coefficient of tantalum pentoxide to values below 0.05 and below 0.01, respectively, at each wavelength within a range from at least 300 nm to about 800 nm. Notably, under such non-obviously modified sputtering process, the values of the refractive index of the deposited Ta₂O₅ film have been sufficiently controlled to remain well above the minimum value practically useful for efficient formation of a metasurface-based devices. Table 1 summarizes a portion of experimentally-measured data corresponding to curves c, c1, while FIGS. 1B, 1C, 1D present these curves within the specified sub-ranges of available data.

TABLE 1

| Free-space wavelength, λ, | n | k |
|---|---|---|
| 273.600159 | 2.798998 | 0.127363 |
| 275.190277 | 2.78002 | 0.109975 |
| 276.780426 | 2.760954 | 0.09411 |
| 278.370605 | 2.741894 | 0.079712 |
| 279.960846 | 2.722926 | 0.066724 |
| 281.551117 | 2.704128 | 0.055088 |
| 283.141449 | 2.68557 | 0.044745 |
| 284.731842 | 2.667319 | 0.035635 |
| 286.322266 | 2.649434 | 0.027702 |
| 287.91272 | 2.63197 | 0.020887 |
| 289.503235 | 2.61498 | 0.015134 |
| 291.093811 | 2.598516 | 0.01039 |
| 292.684387 | 2.582628 | 0.0066 |
| 294.275024 | 2.567372 | 0.003716 |
| 295.865692 | 2.552811 | 0.001686 |
| 297.456421 | 2.539028 | 0.000465 |
| 299.04718 | 2.526164 | 0.000006 |
| 300.638 | 2.514523 | 0 |
| 302.228821 | 2.503813 | 0 |
| 303.819702 | 2.493806 | 0 |
| 305.410645 | 2.484389 | 0 |
| 307.001587 | 2.475485 | 0 |
| 308.59259 | 2.467035 | 0 |
| 310.183624 | 2.458994 | 0 |
| 311.774689 | 2.451323 | 0 |
| 313.365784 | 2.44399 | 0 |
| 314.95694 | 2.436969 | 0 |
| 316.548126 | 2.430235 | 0 |
| . . . | . . . | . . . |
| 400.916565 | 2.254216 | 0 |
| 499.628357 | 2.185554 | 0 |
| 599.826599 | 2.152493 | 0 |
| 699.786194 | 2.132942 | 0 |
| 800.951294 | 2.119335 | 0 |
| 900.026001 | 2.10907 | 0 |
| 998.461426 | 2.10048 | 0 |
| 1100.222168 | 2.092509 | 0 |
| 1199.17749 | 2.085205 | 0 |
| 1301.944092 | 2.077802 | 0 |
| 1401.670898 | 2.070619 | 0 |
| 1501.7771 | 2.063291 | 0 |
| 1602.262451 | 2.055734 | 0 |
| 1689.192139 | 2.048987 | 0 |

In one specific example, other conditions of the process of deposition of the reform layer included: RF power of about 400 W, Ar-gas flow rate (in addition to the use of O₂) of about 50 sccm, base pressure of about 5e⁻⁶ Torr, with the film deposition rate of about 0.336 nm/s.

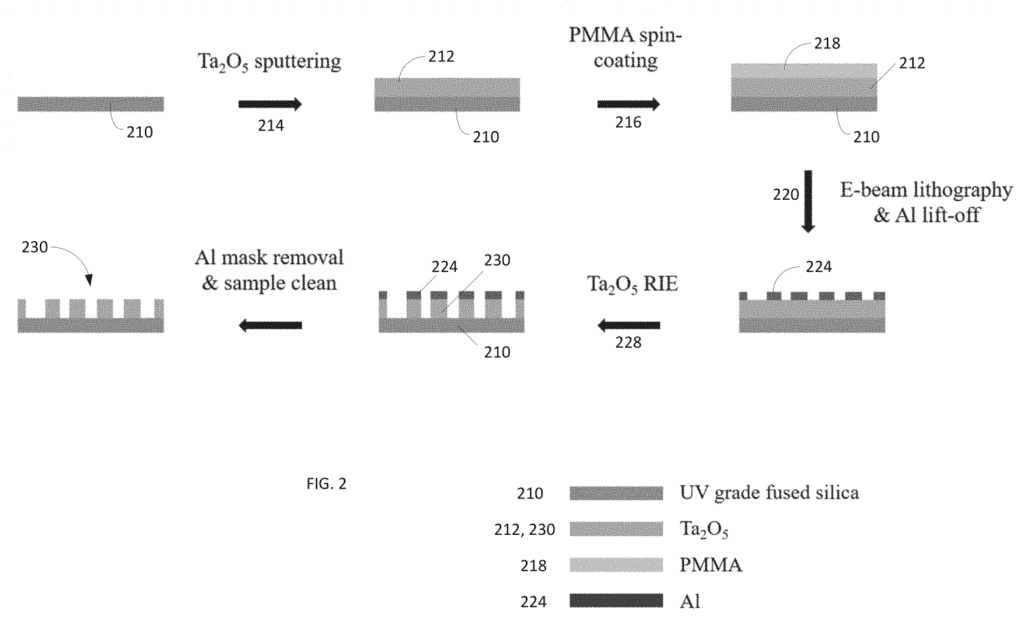

FIG. 2 presents a flow-chart 200 of the fabrication process of a patterned tantalum pentoxide layer on the UV-grade fused silica substrate 210. After the sputtering of the preform layer 212 at step 214, carried out under the judiciously-modified—as compared to the traditional sputtering process—conditions, and spin coating 216 of the PMMA layer 218 on the preform layer 212, e-beam lithography was used to define the metasurface patterns in the PMMA layer. After the development of the resist 218, the patterns were transferred 220 to an Al layer 224 using metal lift-off. Then with the use of the reactive ion etching 228 with fluorine gas and patterned Al layer 224 as the etching mask, the spatial patterns were transferred into the preform layer 212 to generate a spatially-patterned layer 230 of tantalum pentoxide. Notably, unlike in the field of fabrication of waveguides and/or micro-resonators, for example, where the resist layer is conventionally used as the etching mask characterized by the thickness of a few hundreds of nanometers, in the current case of formation of UV-region metasurfaces the direct use of resist as the etching mask was proven to be infeasible due to the need to form the small-scale patterns spatially-tightly packed together with spacing typically smaller than 100 nm. This practical limitation did not permit the use of the methodologies available in the field of integrated optics, forcing the need to additionally employ the metal lift-off processing step. Due to the limitation of the metal lift-off processing, however, the Al mask has to be limited in thickness to only tens of nanometers, forcing yet another modification of the RIE process to ensure that such a thin Al mask be sufficient for etching a preform Ta₂O₅ film 212.

The device fabrication generally included key steps such as Ta₂O₅ film deposition using the developed reactive sputtering recipe, electron beam lithography, Aluminum (Al) etching mask lift-off, and RIE of Ta₂O₅ with a gas mixer of C₄F₈, O₂ and He. In one specific example, the used etching chemistry (of the RIE process) for Ta₂O₅ was Ta₂O₅+C₄F₈+O₂→TaFₓ+CoFₓ+COₓ.

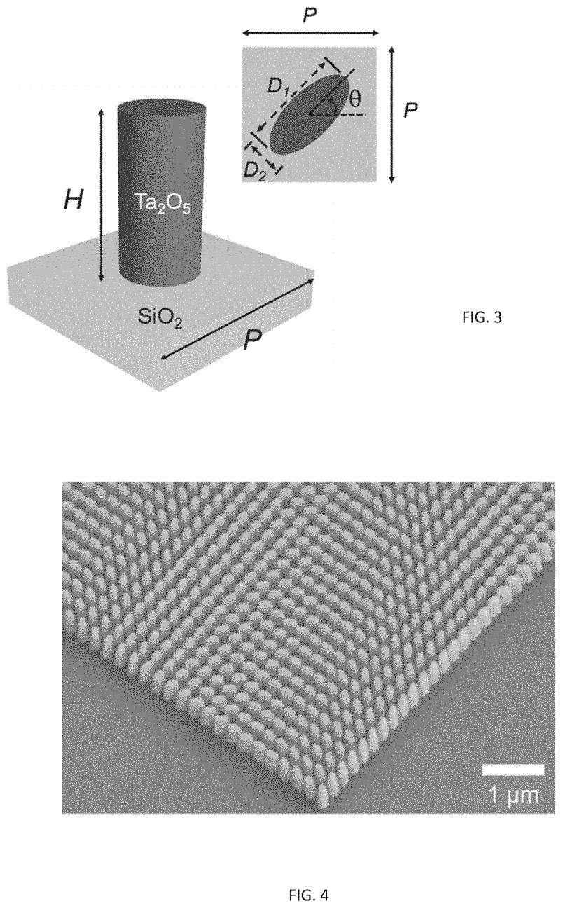

Referring now to FIGS. 3, 4,5, and 6 and to demonstrate the fabrication and practical use of at least one of Ta₂O₅-metasurface-based devices, with the obtained according to the idea of the invention low-loss Ta₂O₅ preform film and the following demonstration of successful patterning of arrays of columns (FIG. 3, with the aspect ratio of at least 5, and in one case within the range from 5 to about 6) in such film with the use of etching methodologies, we implemented broadband, Pancharatnam-Berry (PB) phase-based UV metaholograms as a proof-of-concept demonstration.

An SEM image and a schematic illustration of such metahologram are presented in FIG. 4. The metasurface included elliptical Ta₂O₅ nano-pillars on a UV grade fused silica substrate, designed to operate as nanoscale half waveplates at λ₀=325 nm. The phase shift profile for producing the holographic image was generated by the Gerchberg-Saxton algorithm and implemented by the spatially variant rotation angles of the nano-pillars. To design such metahologram, the transmittance and phase shift for propagation of 325-nm-wavelength light, linearly-polarized either (i) parallel to one principle axis I (T₁ and Δ₁), or (ii) parallel to the other principle axis II (T₂ and Δ₂) of an array of elliptical Ta₂O₅ pillars was computed using the finite-difference-time-domain (FDTD) simulations with periodic boundary conditions. For a chosen in this specific example pillar height H=500 nm and lattice spacing P=180 nm (generally, the lattice spacing was chosen between about 50 nm and about 600 nm), the major and minor axis lengths, D₁ and D₂, were iteratively varied to identify orthogonal principle axis combinations simultaneously leading to |Δ₁−Δ₂|≈π and T₁≈T₂ (in other words, achieving a half-wave-plate-like operation). To facilitate the above parameter search process, a figure-of-merit (FoM) function was defined as

$$FoM = {log}_{10} ( \vert \frac{\text{?}}{\text{?}} \text{?} - \text{?} \vert ) . \\ \text{?} \text{indicates text missing or illegible when filed}$$

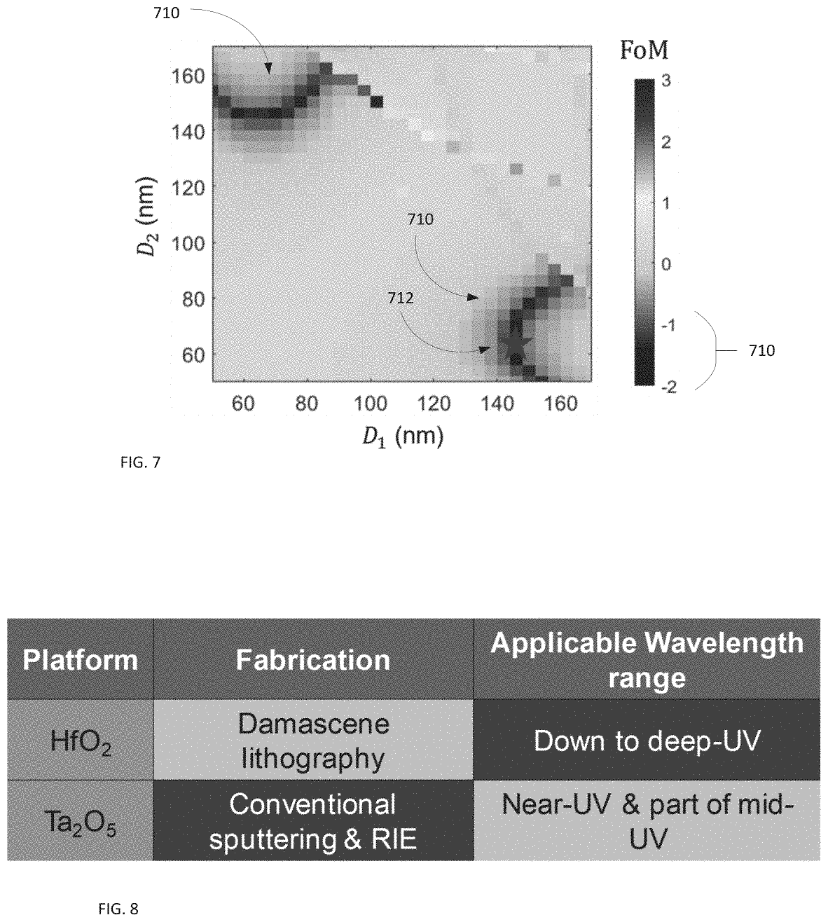

The distribution of this FoM is displayed in FIG. 7, where the blue-colored regions (denoted 710) correspond to various combinations of D₁ and D₂ that satisfy the targeted half-wave-plate-like operation. The chosen pillar geometry in this study (D₁=146 nm and D₂=60 nm) is marked by a star 712. Due to the unprecedentedly low-loss nature of Ta₂O₅ preform layer across the targeted near- and mid-UV spectral regions due to the implementation of the idea of the invention, and due to the optimized nanopillar geometry, the metahologram was shown to operate over a broad UV spectral range.

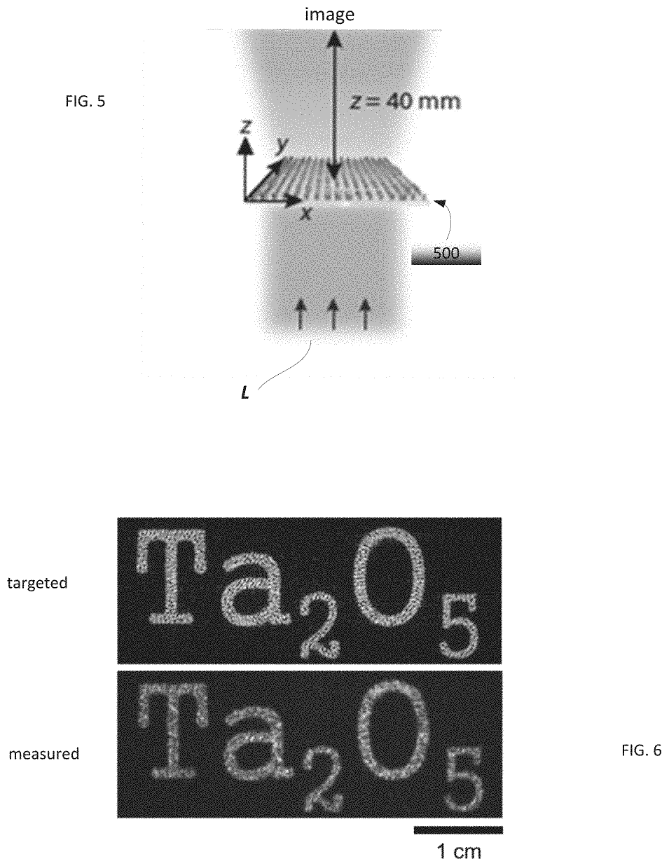

Referring again to FIGS. 5 and 6, under a left-handed circularly polarized (LCP) light illumination L at λ₀=325 nm, the fabricated metasurface projects a “Ta₂O₅” holographic image located 40 mm beyond the device. The experimental holographic image faithfully replicated the shape of the corresponding target image, including subtle details of the chosen font (FIG. 6). The measured efficiency, defined as the ratio of the total power of the holographic image to the power of light illuminating the structure, was ˜40%. This was attributed to the non-ideal etching profiles of the Ta₂O₅ pillars and can be improved by optimizing the RIE process.

With the knowledge of the details of the implementation of some embodiments of the invention, a skilled artisan will now readily appreciate that the discussed methodology enables and facilitates the design and fabrication of various optical devices based on the tantalum-pentoxide metasurfaces. Such devices include and are not limited to a metalens, a beam generator, a metahologram, and additional optical components the examples of which (fabricated with a related optical material HfO₂) were discussed in detail in the U.S. patent application Ser. No. 17/136,277 that provided examples of designs of specific optical elements. In general, embodiments of the invention provide a sub-wavelength-scaled pattern structure made of tantalum pentoxide that is dimensioned to operate as at least one refractive, diffractive, birefringent, and resonant optical elements at an operational wavelength defined in a mid-UV or a near-UV range of the electromagnetic spectrum.

The proposed embodiments understandably complement and/or provide the alternative to the HfO₂-based devices discussed in U.S. patent application Ser. No. 17/136,277 that were shown to operate across the whole near-UV and mid-UV ranges, and most of the deep-UV range but that require a sophisticated Damascene-type process to be fabricated. Implementations of the invention illustrate the novel practical use of a dielectric material that enables high-performance metasurfaces operating in the near-UV regime, and part of the mid-UV regime. In advantageous contradistinction with the use of HfO₂, embodiments of current invention only require conventional sputtering and RIE to be fabricated. Additionally, since Ta₂O₅ possesses a large nonlinear coefficient, the implementation of nonlinear tantalum-pentoxide-based metasurfaces is also enabled.

Features of the specific implementation(s) of the idea of the invention is described with reference to corresponding drawings, in which like numbers represent the same or similar elements wherever possible. In the drawings, the depicted structural elements are generally not to scale, and certain components are enlarged relative to the other components for purposes of emphasis and understanding. It is to be understood that no single drawing is intended to support a complete description of all features of the invention. In other words, a given drawing is generally descriptive of only some, and generally not all, features of the invention. A given drawing and an associated portion of the disclosure containing a description referencing such drawing do not, generally, contain all elements of a particular view or all features that can be presented is this view, for purposes of simplifying the given drawing and discussion, and to direct the discussion to particular elements that are featured in this drawing. A skilled artisan will recognize that the invention may possibly be practiced without one or more of the specific features, elements, components, structures, details, or characteristics, or with the use of other methods, components, materials, and so forth. Therefore, although a particular detail of an embodiment of the invention may not be necessarily shown in each and every drawing describing such embodiment, the presence of this detail in the drawing may be implied unless the context of the description requires otherwise. In other instances, well known structures, details, materials, or operations may be not shown in a given drawing or described in detail to avoid obscuring aspects of an embodiment of the invention that are being discussed.

A person of ordinary skill in the art will readily appreciate that references throughout this specification to “one embodiment,” “an embodiment,” “a related embodiment,” or similar language mean that a particular feature, structure, or characteristic described in connection with the referred to “embodiment” is included in at least one embodiment of the present invention. Thus, appearances of the phrases “in one embodiment”, “in an embodiment”, and similar language throughout this specification may, but do not necessarily, all refer to the same embodiment. Accordingly—as the skilled artisan will readily appreciate—while in this specification the embodiments have been described in a way that enables a clear and concise specification to be written, it is intended that substantially none of the described embodiments can be employed only by itself to the exclusion of other embodiments (to the effect of practically restriction of some embodiments at the expense of other embodiments), and that substantially any of the described embodiments may be variously combined or separated to form different embodiments without parting from the scope of the invention.

The invention as recited in claims appended to this disclosure is intended to be assessed in light of the disclosure as a whole.

What is claimed is:

1. A method comprising:
forming a preform layer by reactive sputtering, in a sputtering chamber, of tantalum pentoxide on a chosen substrate while simultaneously reducing an extinction coefficient of said preform layer below 0.1 at each target wavelength within a range from at least 277 nm to about 800 nm;
etching said preform layer to form the sub-wavelength-scaled pattern structure that is dimensioned to operate as at least one of a refractive optical element, a diffractive optical element, a birefringent optical element, and a resonant optical element at an operational wavelength in a mid-ultraviolet (UV) range and/or a near-UV range of an electromagnetic spectrum.

2. The method according to claim 1, wherein said forming includes simultaneously reducing the extinction coefficient to a value below 0.01 at each wavelength within a range from at least 292 nm to about 800 nm, and wherein said operational wavelength is within a spectral range from about 280 nm to about 380 nm.

3. The method according to claim 2, wherein said forming further includes simultaneously reducing the extinction coefficient to a value below 0.001 at each wavelength within a range from about 800 nm to about 1700 nm.

4. The method according to claim 1, wherein said forming includes simultaneously reducing the extinction coefficient to a value below 0.00001 at each wavelength within a range from at least 299 nm to about 800 nm, and wherein said operational wavelength is within a spectral range from about 280 nm to about 380 nm.

5. The method according to claim 1, wherein said etching includes forming said pattern structure that includes only tantalum pentoxide.

6. The method according to claim 1, wherein said forming includes varying a flow of oxygen into said sputtering chamber.

7. The method according to claim 1, wherein said forming includes the sputtering of tantalum pentoxide while simultaneously maintaining a refractive index of said preform layer above 2.21 at each first wavelength within a range from at least 277 nm to about 800 nm.

8. The method according to claim 7, wherein said forming includes the sputtering of tantalum pentoxide while simultaneously maintaining the refractive index of said preform layer above 2.0 at each second wavelength within a range from about 800 nm to about 1700 nm.

9. The method according to claim 7, wherein said simultaneously maintaining includes delivering a flow of oxygen into said sputtering chamber at a rate of at least 2 standard cubic centimeters per minute (sccm).

10. The method according to claim 1, wherein said etching includes generating an array of cylindrical columns of tantalum pentoxide of sub-micron height and aspect ratios of at least 5, an aspect ratio of a respective columns defined as a ratio of a height to a transverse dimension thereof.

11. The method according to claim 1, wherein said etching includes generating an array of columns of tantalum pentoxide of a sub-micron height wherein said array is a spatially-periodic array with a spatial period having a value within a range from about 50 nm to about 600 nm.

12. The method according to claim 1, wherein said etching includes forming an array of cylindrical pillars having different diameters to form areas of the array having different filling factors.

13. The method for operating an optical component containing the pattern structure fabricated according to claim 1, the method for operating comprising at least one of the following steps:
(13a) changing at least one of a direction of propagation and a degree of divergence of light at the operational wavelength by transmitting said light through the pattern structure with efficiency of at least 40%;
(13b) forming an image of an object in said light at the operational wavelength emanating from the object with the use of said pattern structure; and
(13c) transmitting said light at the operational wavelength through said pattern structure without forming non-zero diffractive orders of said light.

14. A method for fabricating an all-dielectric metasurface optical device including at least one of a polarization-independent metalens, a polarization-independent metahologram, a polarization-independent Airy beam generator, the method comprising:
utilizing tantalum pentoxide material target to deposit and etch, on a chosen substrate, a tantalum pentoxide layer that has a submicron thickness and an extinction coefficient smaller than 0.1 at each target wavelength within a range from at least 277 nm to about 1700 nm;
wherein said device has optical transmittance of at least 40% at every operational wavelength within a range from about 280 nm to about 380 nm.

15. A metasurface comprising:
an optical substrate, and
a spatially-periodic two-dimensional array of cylindrical pillars oriented on the optical substrate substantially normally to the optical substrate, the cylindrical pillars including tantalum pentoxide that has extinction coefficient of less than 0.1 at each target wavelength within a range from at least 277 nm to about 1700 nm;
wherein a spatial period P of said array is substantially constant across an area of the optical substrate occupied by the array while different cylindrical pillars have different diameters to form areas of the array having different filling factors and heights of the cylindrical pillars in the array approximately equal or exceed a free-space operational wavelength chosen within a mid-UV region and a near-UV region of the electromagnetic spectrum such that the metasurface is configured to operate, in transmission of light at said operational wavelength, as at least one of a refractive optical element, a diffractive optical element, a birefringent optical element, and a resonant optical element.

16. The metasurface according to claim 15, wherein a cylindrical pillar in said array is dimensioned as an elliptic cylinder and the spatial period P does not exceed the operational wavelength to not have said light, incident onto the metasurface, diffract upon transmission through the metasurface.

17. The metasurface according to claim 15,
wherein said operational wavelength is within a range from about 280 nm to about 380 nm, and
wherein a refractive index value of said tantalum pentoxide is greater than 2.0 at each target wavelength.

18. The metasurface according to claim 17, wherein the refractive index of said tantalum pentoxide is higher than 2.2 at each wavelength between 280 nm and 380 nm.

19. The metasurface according to claim 17, wherein said extinction coefficient is below 0.001 at each wavelength from at least 297 nm to about 1700 nm.

20. The metasurface according to claim 17, wherein said extinction coefficient is below 0.00001 at each wavelength from at least 299 nm to about 1700 nm.
